(19) United States
(12) Patent Application Publication
(10) Pub. No.: US 2026/0173396 A1
(43) Pub. Date: Jun. 18, 2026

(54) FERROELECTRIC NOR MEMORY ARCHITECTURES

(71) Applicant: Micron Technology, Inc., Boise, ID (US)

(72) Inventors: Lorenzo Fratin, Buccinasco (MI) (IT); Fabio Pellizzer, Boise, ID (US)

(21) Appl. No.: 19/393,383

(22) Filed: Nov. 18, 2025

Related U.S. Application Data
(60) Provisional application No. 63/734,542, filed on Dec. 16, 2024.

(51) Int. Cl. H10B 51/30; G11C 11/22; H10B 51/10; H10B 51/20

(52) U.S. Cl. CPC H10B 51/30; G11C 11/223; G11C 11/2273; G11C 11/2275; H10B 51/10; H10B 51/20

(57) ABSTRACT

Methods, systems, and devices for ferroelectric NOR memory architectures are described. A memory device may include a first pillar, a second pillar, and a third pillar positioned between the first and second pillars. The memory device may include multiple first memory cells positioned between a respective first word line and a first semiconductor material at a first side of the third pillar and multiple second memory cells positioned between a respective second word line and the first semiconductor material at a second side of the third pillar. The memory device may include multiple first portions and second portions of a second semiconductor material, where each first portion couples a respective first memory cell and a respective second memory cell to the first pillar, and where each second portion couples a respective first memory cell and a respective second memory cell to the second pillar.

### CROSS REFERENCE

The present Application for Patent claims priority to U.S. Patent Application No. 63/734,542 by Fratin et al., entitled “FERROELECTRIC NOR MEMORY ARCHITECTURES,” filed Dec. 16, 2024, which is assigned to the assignee hereof, and which is expressly incorporated by reference in its entirety herein.

### TECHNICAL FIELD

The following relates to one or more systems for memory, including ferroelectric NOR memory architectures.

### BACKGROUND

Memory devices are used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored by the memory cell. To store information, a memory device may write (e.g., program, set, assign) states to the memory cells. To access stored information, a memory device may read (e.g., sense, detect, retrieve, determine) states from the memory cells.

### BRIEF DESCRIPTION OF THE DRAWINGS

FIG. 1 shows an example of a memory device that supports ferroelectric NOR (FeNOR) memory architectures in accordance with examples as disclosed herein.

FIGS. 2A and 2B show examples of an architecture that supports FeNOR memory architectures in accordance with examples as disclosed herein.

FIGS. 3A and 3B show an example of an architecture that supports FeNOR memory architectures in accordance with examples as disclosed herein.

FIG. 4 shows a block diagram of a memory device that supports FeNOR memory architectures in accordance with examples as disclosed herein.

FIG. 5 shows a flowchart illustrating a method or methods that support FeNOR memory architectures in accordance with examples as disclosed herein.

### DETAILED DESCRIPTION

Some memory devices may implement a ferroelectric material in memory cells that are arranged Not-AND (NAND) architecture, such as a three-dimensional (3D) or vertical NAND architecture. For example, a ferroelectric material may be implemented in addition to a charge-trapping material, or instead of a charge trapping material, of a memory cell that alters (e.g., in accordance with a stored logic state, in accordance with a stored electric field) an activation voltage for a semiconductor channel associated with the memory cell (e.g., a channel associated with a stack or memory cells, a channel associated with a pillar of memory cells). In some examples, a memory device with such an implementation of a ferroelectric material may experience relatively faster programming (e.g., in accordance with a polarization change of the ferroelectric material, in accordance with a change in dipole polarization) or relatively lower power consumption (e.g., by reducing or avoiding electron transfer associated with a charge trapping material, with relatively lower write voltages) than a memory device with other implementations of charge-trapping materials. However, some implementations of ferroelectric material in a memory array may have other performance tradeoffs. For example, some implementations of a ferroelectric material in such architectures may be associated with relatively high read latency, a relatively high erase latency, or both (e.g., due to relatively low current in vertical channels of a 3D NAND array, due to a relatively high capacitance of planar word lines implemented in a 3D NAND array, or both).

In accordance with the techniques described herein, ferroelectric memory cells may be implemented in accordance with a Not-OR (NOR) architecture (e.g., a ferroelectric NOR (FeNOR) architecture, a 3D FeNOR architecture), in which each memory cell along a column of the NOR architecture may be connected with (e.g., between) vertical source lines and bit lines (e.g., also referred to as drain lines). For example, a memory array implementing a FeNOR architecture may include first pillars (e.g., conductive pillars, conductors, each associated with a first access line, such as a bit line or source line), second pillars (e.g., conductive pillars, conductors, each associated with a second access line, such as a bit line or drain line), and third pillars each positioned between respective first and second pillars. Each of the third pillars may include a first semiconductor material that extends along the third pillar (e.g., along a length direction, along a height direction). The memory array may also include multiple first memory cells (e.g., associated with first transistors including a ferroelectric material) along a given third pillar that are each positioned between a respective first word line and the first semiconductor material at a first side of the third pillar, and multiple second memory cells (e.g., associated with second transistors including a ferroelectric material) along the given third pillar that are each positioned between a respective second word line and the first semiconductor material at a second side of the third pillar. To form semiconductor channels associated with the first and second memory cells (e.g., between a first pillar and a second pillar), the memory device may include multiple portions of a second semiconductor material (e.g., having a different doping configuration than the first semiconductor material) between the first semiconductor material and each of the respective first and second pillars. Thus, an FeNOR memory array may include stacks of memory cells (e.g., along one or more sides of a given pillar of memory cells), which may be configured to support an improved balance of read latency, write latency, power consumption, and storage volatility compared with other implementations and architectures.

In addition to applicability in memory systems as described herein, techniques for FeNOR architectures may be generally implemented to improve the performance of various electronic devices and systems (including artificial intelligence (AI) applications, augmented reality (AR) applications, virtual reality (VR) applications, and gaming). Some electronic device applications, including high-performance applications such as AI, AR, VR, and gaming, may be associated with relatively high processing requirements to satisfy user expectations. As such, increasing processing capabilities of the electronic devices by decreasing response times, improving power consumption, reducing complexity, increasing data throughput or access speeds, decreasing communication times, or increasing memory capacity or density, among other performance indicators, may improve user experience or appeal. Implementing the techniques described herein may improve the performance of electronic devices by providing for an increased quantity of memory cells (e.g., NOR memory cells) arranged in a pier and pillar architecture, which may decrease latency associated with read and programming operations, improve random access speeds, and reduce power consumption, among other benefits.

Features of the disclosure are illustrated and described in the context of memory devices and related circuitry. Features of the disclosure are further illustrated and described in the context of architectures, memory devices, and flowcharts.

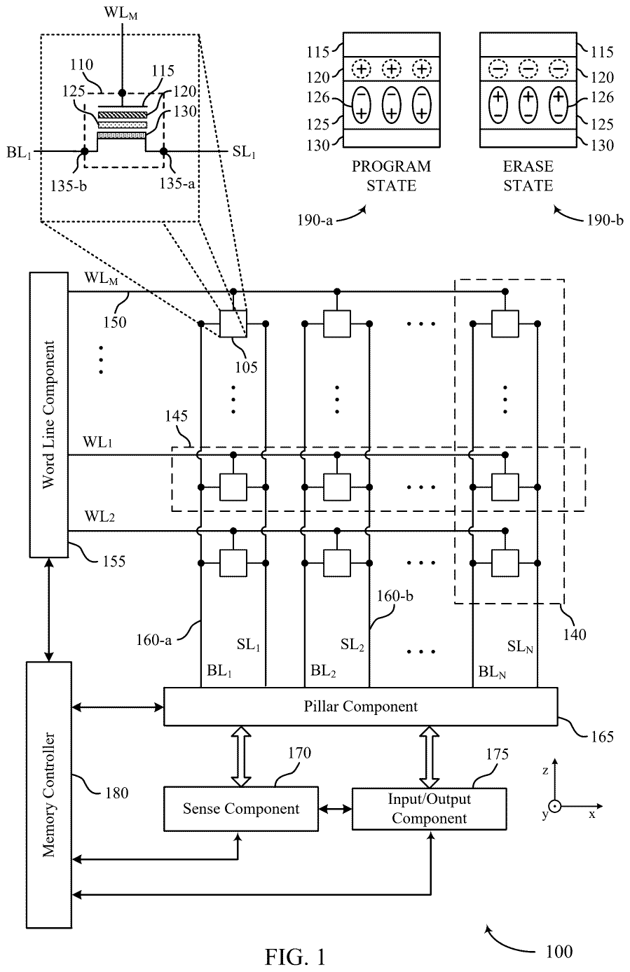

FIG. 1 shows an example of a memory device 100 that supports FeNOR memory architectures in accordance with examples as disclosed herein. The memory device 100 may be referred to as a memory die or an electronic memory apparatus, and include one or more arrays of memory cells 105. FIG. 1 is an illustrative representation of various components and features of the memory device 100. As such, the components and features of the memory device 100 are shown to illustrate functional relationships, and not necessarily physical positions within the memory device 100. Further, although some elements included in FIG. 1 are labeled with a numeric indicator, some other corresponding elements are not labeled, even though they are the same or would be understood to be similar, in an effort to increase visibility and clarity of the depicted features. Aspects of the memory device 100 may be described with reference to an x-direction, a y-direction, and a z-direction of the illustrated coordinate system.

A memory device 100 may implement non-volatile memory cells that are based on ferroelectric properties of various materials, such as dopant-free hafnium oxide (HfOx) or hafnium zirconium oxide (HfZrOx), among other examples. Such memory cells may be referred to as ferroelectric field-effect transistor (Fe-FETs) memory cells and may, in some examples, be implemented in a NAND architecture (e.g., 3D NAND architecture) by replacing or combining a charge-trapping material in a gate dielectric stack with a ferroelectric material. Compared with a charge-trapping material, which may store an electric field based on electron transfer into or out of the charge-trapping material (e.g., by way of hot electron tunneling, by way of Fowler-Nordheim (FN) tunneling), a ferroelectric material may store an electric field by way of polarization (e.g., a dipole polarization, a polarization orientation, a dipole orientation, an electric field orientation, with or without an accompanying electron transfer) of the ferroelectric material, which may be associated with a switching mechanism of ferroelectric dipoles of the ferroelectric material. In some examples, such an implementation may support relatively faster programming (e.g., in accordance with a polarization change of the ferroelectric material) or relatively lower power consumption than a memory device with other implementations of charge-trapping materials or NAND architectures (e.g., associated with a reduction of electron transfer to write or erase a given logic state, associated with relatively lower voltages to induce a dipole polarization than perform charge transfer). However, some such implementations of ferroelectric material may have other performance tradeoffs. For example, some implementations of a ferroelectric material in such architectures may be associated with relatively high read latency, a relatively high erase latency, or both (e.g., due to relatively low current in vertical channels of a 3D NAND array, due to a relatively high capacitance of planar word lines implemented in a 3D NAND array, or both), or may prevent byte alterability (e.g., due to an erase granularity being different than a write granularity), among other drawbacks.

In accordance with the techniques described herein, to improve performance of memory cells 105 within a dense array, the memory device 100 may implement a NOR structure, where each memory cell 105 along a column of the array may be connected to vertical source lines and bit lines (e.g., otherwise referred to as drain lines, along the z-direction). For example, the memory device 100 may implement an architecture that integrates a relatively high-density array of Fe-FETs in a NOR configuration, thereby enabling the memory device 100 to realize improved read and program performance, relatively quicker random-access procedures, relatively improved byte alterability, and experience reduced power consumption (e.g., lower energy) for a variety of applications.

For example, the memory device 100 may include memory cells 105 that are programmable to store different logic states. In some cases, a memory cell 105 may be programmable to store two logic states, denoted a logic 0 and a logic 1. In some cases, a memory cell 105 may be programmable to store more than two logic states (e.g., as a multi-level cell). The memory cells 105 may be part of an array (e.g., a memory array) of the memory device 100, where, in some examples, an array may refer to a contiguous set of memory cells 105 (e.g., a contiguous set of elements of a semiconductor chip).

Each memory cell 105 may be implemented as a transistor (e.g., an Fe-FET) that is configured for storing an electric field representative of a logic state. For example, the blow-up of FIG. 1 illustrates a memory cell 105 (e.g., an FeNOR memory cell, an FeFET memory cell, a ferroelectric memory cell) that includes a transistor 110 that may be used to store a logic value. The transistor 110 may include a gate 115 (e.g., a gate portion, a control gate), a dielectric portion 120 (e.g., a gate dielectric), a ferroelectric portion 125 (e.g., a polarization portion, a portion including ferroelectric dipoles 126, a portion for storing an electric field corresponding to a logic state), a channel interlayer portion (not shown), and a channel portion 130 (e.g., including one or more semiconductor material portions, a doped semiconductor channel). The transistor 110 also may include a first node 135-a (e.g., a source or drain associated with the channel portion 130) and a second node 135-b (e.g., a drain or source associated with the channel portion 130). An electric field stored at a memory cell 105 (e.g., stored at least in part by a polarization of a ferroelectric portion 125) may affect the threshold voltage of the transistor 110 (e.g., a voltage at a gate 115 to activate the channel portion 130, an activation voltage), thereby affecting an amount of current that may through the transistor 110 when the gate 115 is biased (e.g., when a voltage is applied to the gate 115, when a voltage is applied to a word line 150, when the memory cell 105 is read).

A logic value may be stored in a memory cell 105 (e.g., in a transistor 110) by inducing (e.g., writing, storing) an electric field in the memory cell 105. For example, an electric field corresponding to a logic state may be stored based at least in part on storing a polarization (e.g., a dipole polarization, a polarization orientation, a dipole orientation, a local electric field orientation) in a ferroelectric portion 125, where different polarizations may correspond to different logic states. For example, a memory cell 105 may be written with a cell state 190 (e.g., an electric field state, a polarization state, a written state, corresponding to a logic state), such as either a cell state 190-a (e.g., a “PROGRAM” state) or a cell state 190-b (e.g., an “ERASE” state). In the illustrated examples, a cell state 190-a may correspond to a first polarization of a ferroelectric portion 125 (e.g., a first orientation of dipoles 126, corresponding to a positive local electric field from a gate 115 to a channel portion 130), and a cell state 190-b may correspond to a second polarization of a ferroelectric portion 125 (e.g., a second orientation of dipoles 126, corresponding to a negative local electric field from a gate 115 to a channel portion 130). In some examples, the cell state 190-a may be associated with supporting a relatively lower voltage at a gate 115 to activate a channel portion 130 (e.g., a relatively higher activation voltage, a relatively lower conductivity through the channel portion 130 for a given voltage at the gate 115), whereas the cell state 190-b may be associated with supporting a relatively higher voltage at a gate 115 to activate a channel portion 130 (e.g., a relatively lower activation voltage, a relatively higher conductivity through the channel portion 130 for the given voltage at the gate 115).

In some examples, an electric field corresponding to a logic state may also be associated with storing an electric charge, such as by way of electron transfer into or out of a portion of the memory cell 105 (e.g., a dielectric portion 120, a channel interlayer portion, a charge trapping material included in combination with a ferroelectric portion 125, the ferroelectric portion 125 itself, or a combination thereof). For example, an electric field associated with the cell state 190-a may also include a net positive charge (e.g., in addition to a polarization of a ferroelectric portion 125, as stored in a dielectric portion 120, as a result of transferring electrons from the memory cell 105, as a result of hole injection), and an electric field associated with the cell state 190-b may also include a net negative charge (e.g., in addition to a polarization of a ferroelectric portion 125, as stored in a dielectric portion 120, as a result of transferring electrons into the memory cell 105, as a result of electron injection).

In the example of memory device 100, the memory cells 105 may be configured in planes 145 (e.g., in an xy-plane, memory cells 105 arranged along the x-direction and the y-direction) and along pillars 140 (e.g., third pillars including memory cells 105 arranged along the z-direction). For example, a plane 145 of memory cells 105, or subset thereof, may be coupled with a respective word line 150 (e.g., WL₁ through WL_{M}, a planer word line, a word line comb), and each pillar 140 of memory cells 105 may be coupled with a respective bit line 160-a (e.g., BL₁ through BL_{N}) and a respective source line 160-b (e.g., SL₁ through SL_{N}). Each of the word lines 150, bit lines 160-a, and source lines 160-b may be an example of an access line of the memory device 100. In the example of memory device 100, one memory cell 105 may be located at the intersection of (e.g., coupled with, coupled between) a word line 150 and a paired bit line 160-a and source line 160-b. This intersection may be referred to as an address of a memory cell 105. A target (e.g., selected) memory cell 105 may be a memory cell 105 located at the intersection of an activated or otherwise selected word line 150 and an activated or otherwise selected bit line 160-a and source line 160-b.

The memory device 100 may include a 3D memory array, where multiple two-dimensional (2D) memory arrays (e.g., planes 145, in xy-planes) may be formed on top of one another (e.g., along the z-direction). In some examples, such an arrangement may increase the quantity of memory cells 105 that may be fabricated on a single die or substrate as compared with 2D arrays, which, in turn, may reduce production costs, or increase the performance of the memory array, or both. In the example of FIG. 1, memory device 100 includes multiple planes 145 (e.g., decks, layers, levels, tiers) of memory cells 105. The planes 145 (e.g., word lines 150) may, in some examples, be separated by an electrically insulating material. Each plane 145 may be aligned or positioned so that memory cells 105 may be aligned (e.g., exactly aligned, overlapping, or approximately aligned) with one another across each plane 145, forming a memory cell 105 stack along the z-direction (e.g., along a pillar).

Access operations such as reading, writing, rewriting, and refreshing may be performed on a memory cell 105 by activating (e.g., selecting) a word line 150, a bit line 160-a, and a source line 160-b coupled with the memory cell 105, which may include applying a voltage, a charge, or a current to the respective access line. After selecting a memory cell 105 (e.g., in a read operation), a resulting signal may be used to determine the logic state stored by the memory cell 105.

Accessing memory cells 105 may be controlled using a word line component 155 (e.g., a row decoder, a word line decoder), a pillar component 165 (e.g., a pillar decoder, a column decoder), or both, among other component architectures. For example, the word line component 155 may receive a row address from the memory controller 180 and activate a corresponding word line 150 based on the received row address. Similarly, the pillar component 165 may receive a column address from the memory controller 180 and activate a corresponding bit line 160-a and a corresponding source line 160-b.

In some examples, the memory controller 180 may control operations (e.g., read operations, write operations, rewrite operations, refresh operations) of memory cells 105 using one or more components (e.g., word line components 155, pillar components 165, sense components 170, input/output components 175). In some cases, one or more of the word line component 155, the pillar component 165, and the sense component 170 may be co-located with or otherwise included as part of the memory controller 180. The memory controller 180 may generate row and column address signals to activate a desired word line 150, bit line 160-a, and source line 160-b. The memory controller 180 may also generate or control various voltages or currents used during the operation of memory device 100.

A memory cell 105 may be written (e.g., programmed, set) by activating the relevant word line 150, bit line 160-a, and source line 160-b (e.g., via a memory controller 180). In other words, a logic state may be stored in a memory cell 105. A word line component 155, pillar component 165, or both may accept data, for example, via input/output component 175, to be written to the memory cells 105. In some examples, a write operation may be performed at least in part by a sense component 170, or a write operation may be configured to bypass a sense component 170.

A memory cell 105 may be read (e.g., sensed) by a sense component 170 when the memory cell 105 is accessed (e.g., in cooperation with the memory controller 180) to determine a logic state written to or stored by the memory cell 105. For example, the sense component 170 may be configured to evaluate a current or charge transfer through or from the memory cell 105, or a voltage resulting from coupling the memory cell 105 with the sense component 170, responsive to a read operation. The sense component 170 may provide an output signal indicative of the logic state read from the memory cell 105 to one or more components (e.g., to the pillar component 165, the input/output component 175, to the memory controller 180).

A sense component 170 may include various circuitry (e.g., switching components, selection components, transistors, amplifiers, capacitors, resistors, voltage sources) configured to detect or amplify a difference in sensing signals (e.g., a difference between a read voltage and a reference voltage, a difference between a read current and a reference current, a difference between a read charge and a reference charge), which, in some examples, may be referred to as latching. In some examples, a sense component 170 may include a collection of circuit elements that are repeated for each of a set or subset of bit lines 160-a, source lines 160-b, or both that are coupled with the sense component 170. For example, a sense component 170 may include a separate sensing circuit (e.g., a separate or duplicated sense amplifier, a separate or duplicated signal development component) for each of a set of bit lines 160-a, each of a set of source lines 160-b, or both that are coupled with the sense component 170, such that a logic state may be separately detected for respective memory cells 105.

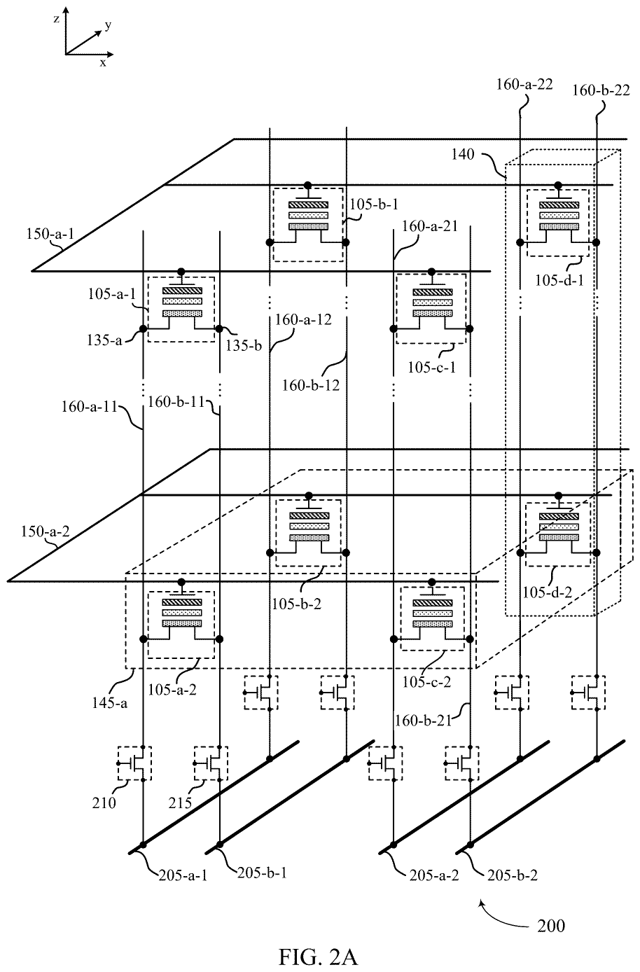

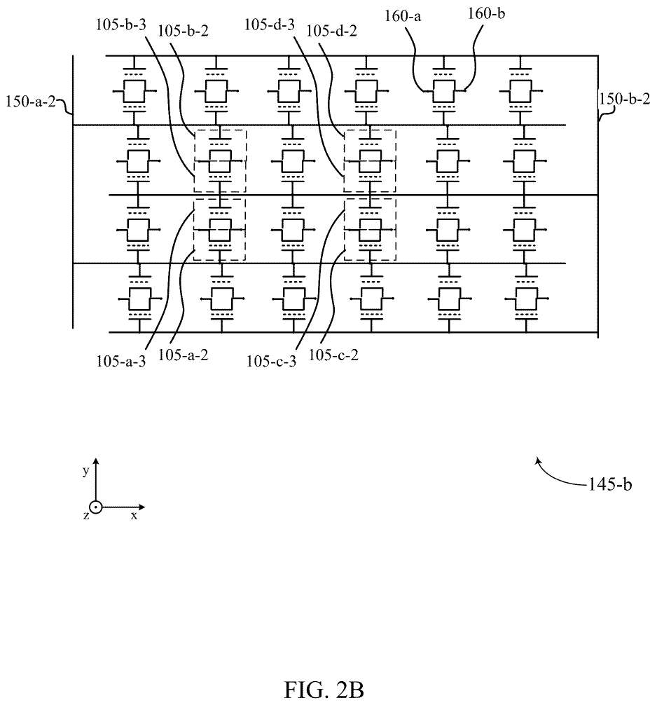

FIGS. 2A and 2B show examples of an architecture 200 (e.g., an array architecture, a memory array) that supports FeNOR memory architectures in accordance with examples as disclosed herein. The architecture 200 may be an example of portions of a memory device, such as a memory device 100. Although some elements of a set of elements (e.g., an array of elements) are included in FIGS. 2A and 2B, some elements may be omitted for the sake of visibility and clarity of the depicted elements. Moreover, although some elements included in FIGS. 2A and 2B are labeled with reference numbers, some other corresponding elements are not labeled, though they would be understood by a person having ordinary skill in the art to be the same as or similar to the labeled elements. Aspects of an architecture 200 may be described with reference to an x-direction, a y-direction, and a z-direction of the illustrated coordinate system.

The architecture 200 illustrates a 3D array of memory cells 105 (e.g., transistors 110), which may be connected in a 3D NOR configuration. For example, memory cells 105 may be arranged according to pillars 140 (e.g., columns, of memory cells 105) along the z-direction, each of which may include one or more (e.g., two) stacks of memory cells 105 along the z-direction. In some examples, each pillar 140 may be associated with a channel (e.g., a semiconductor channel, a semiconductor pillar) along the z-direction. A memory device 100 may include any quantity of one or more pillars 140 in accordance with examples as disclosed herein. In some implementations, each pillar 140 may include a first set of memory cells 105 at a first side of the pillar 140 (e.g., along the y-direction) and include a second set of memory cells 105 at a second side of the pillar 140 opposite the first side (e.g., along the y-direction). As illustrated, a first pillar 140 may include the memory cells 105-d-1 through 105-d-2 (e.g., positioned at a first side of the first pillar 140 along the y-direction) and, in some examples (not shown), may include a second set of memory cells 105 (e.g., positioned at a second side of the first pillar 140). Similarly, another pillar 140 may include the memory cells 105-a-1 through 105-a-2 (e.g., at a first side of the other pillar 140) and, in some examples (not shown), may include a second set of memory cells 105 (e.g., positioned at the second side of the other pillar 140), and so on.

Each pillar 140 may be associated with and positioned between a respective bit line 160-a (e.g., a conductive pillar) and a respective source line 160-b (e.g., a conductive pillar), and each memory cell 105 along a pillar 140 may be coupled with the same bit line 160-a and the same source line 160-b. For example, a same bit line 160-a may be coupled with the first node 135-a (e.g., a drain node) of each memory cell 105 (e.g., transistor 110) of a pillar 140, while a same source line 160-b may be coupled with the second node 135-b (e.g., a source node) of each memory cell 105 (e.g., transistor 110) of the pillar 140. As illustrated, the first nodes 135-a of the memory cells 105-a-1 through 105-a-2 may be coupled with the bit line 160-a-11, while the second nodes 135-b of the memory cells 105-a-1 through 105-a-2 may be coupled with the source line 160-b-11.

In some examples, the bit lines 160-a of one or more pillars 140 (e.g., in a group along the y-direction) may be coupled (e.g., selectively, via a transistor 210, via a pillar component 165) with a same bit line selector 205-a (e.g., an access line, a multiplexing line). For example, the bit line 160-a-11 coupled with memory cells 105-a of one pillar 140 and the bit line 160-a-12 coupled with memory cells 105-b of another pillar 140 may both be coupled (e.g., via a respective transistor 210) with the bit line selector 205-a-1. Likewise, the bit line 160-a-21 coupled with memory cells 105-c of one pillar 140 and the bit line 160-a-22 coupled with memory cells 105-d of another pillar 140 may both be coupled with the bit line selector 205-a-2. Although illustrated as being at a first end (e.g., bottom) of the architecture 200 (e.g., along the z-direction), it should be understood that such bit line selectors 205-a may be positioned at a second end (e.g., top) of the architecture 200 (e.g., along the z-direction). Transistors 210 may be coupled with activation lines (e.g., extending along the x-direction, coupled with gates of the transistors 210) and operated in accordance with various multiplexing and addressing techniques.

In some examples, the source lines 160-b of one or more pillars 140 (e.g., in a group along the y-direction) may be coupled (e.g., selectively, via a transistor 215, via a pillar component 165) with a same source line selector 205-b (e.g., an access line, a multiplexing line, a common source). For example, the source line 160-b-11 coupled with memory cells 105-a of one pillar 140 and the source line 160-b-12 coupled with memory cells 105-b of another pillar 140 may both be coupled (e.g., via a respective transistor 215) with the source line selector 205-a-1. Likewise, the source line 160-b-21 coupled with memory cells 105-c of one pillar 140 and the source line 160-b-22 coupled with memory cells 105-d of another pillar 140 may both be coupled with the source line selector 205-b-2. Although illustrated as being at a first end (e.g., bottom) of the architecture 200 along the z-direction, it should be understood that such source line selectors 205-b may be positioned at a second end (e.g., top) of the architecture 200 along the z-direction. Transistors 215 may be coupled with activation lines (e.g., extending along the x-direction, coupled with gates of the transistors 215) and operated in accordance with various multiplexing and addressing techniques.

In the example of architecture 200, the array of memory cells 105 may also be divided into a set of planes 145 arranged along the z-direction, including the plane 145-a associated with memory cells 105-a-2 through 105-d-2, and so on. In some examples, all memory cells 205 of a plane 145 may be activated by a same word line 150. In some other examples, subsets of memory cells 205 of a given plane 145 may be activated by a respective one of multiple word lines 150 associated with the given plane 145. For example, a plane 145 may be associated with word lines 150 configured in accordance with a comb structure (e.g., even and odd word lines 150). Such combed word lines 150 may be formed such that portions of the word line 150 (e.g., conductor portions, projections, tines) extend along the x-direction through gaps (e.g., alternating gaps) between pillars 140. For example, the architecture 200 may include two word lines 150 per plane 145 (e.g., according to odd word lines 150-a-1 and 150-a-2, with projections along the positive x-direction, and even word lines 150-b-1 (not shown) and 150-b-2 (e.g., as illustrated by the plane 145-b of FIG. 2B), with projections along the negative x-direction, where such word lines 150 of the same plane 145 may be described as being interleaved (e.g., with portions of an odd word line 150-a-2 projecting along the x-direction between portions of an even word line 150-b-2, and vice versa). In some examples, an even word line 150-b (e.g., of a plane 145) may be associated with a first memory cell 105 on a first side (e.g., along the y-direction) of a given pillar 140 and an odd word line 150-a (e.g., of the same plane 145) may be associated with a second memory cell 105 on a second side (e.g., along the y-direction, opposite the first memory cell 105) of the given pillar 140. Thus, in some examples, memory cells 105 of a given plane 145 may be addressed (e.g., selected, activated, multiplexed) in accordance with an even word line 150 or an odd word line 150.

FIG. 2B shows a top-down view of a plane 145-b that may be implemented in the architecture 200, illustrating a combed word line structure. As illustrated, the word line 150-a-2 may have portions that extend (e.g., into the array of memory cells 105) along the positive x-direction, and the word line 150-b-2 may have portions that extend along the negative x-direction. Accordingly, the memory cells 105-a-2, 105-b-2, 105-c-2, and 105-d-2 may be coupled with (e.g., activated by) the word line 150-a-2 (e.g., an odd word line), and the memory cells 105-a-3, 105-b-3, 105-c-3, and 105-d-3 (e.g., opposite the memory cells 105-a-2, 105-b-2, 105-c-2, and 105-d-2 along the y-direction) may be coupled with the word line 150-b-2 (e.g., an even word line).

To operate the architecture 200 (e.g., to perform a program operation, a read operation, or an erase operation on one or more memory cells 105 of a pillar 140), various voltages may be applied to one or more word lines 150 (e.g., to one or more gates of the transistors 110), to one or more bit lines 160-a (e.g., to first node 135-a or drain of one or more transistors 110), to one or more source lines 160-b (e.g., to the second node 135-b or source of the transistors 110), or any combination thereof.

In some cases, as part of a program operation for a target memory cell 105, a polarization (e.g., a dipole polarization, a stored electric field) may be induced by applying an electric field (e.g., a coercive field, a saturation field, a polarizing field) across a ferroelectric portion 125 of the target memory cell 105. Additionally, in some examples, an electric charge may be induced (e.g., injected, by way of charge transfer, by way of electron transfer) based on applying the electric field (e.g., across the memory cell), in which case a charge stored in a charge-trapping material may accompany a polarization to store a logic state at the memory cell 105. In some cases, respective voltages may be applied to word line(s) 150, bit line(s) 160-a, and source line(s) 160-b, such that a gate 115 of the target memory cell 105 is at a higher voltage than the first node 135-a and the second node 135-b of the target memory cell 105 (e.g., a relatively positive voltage may be applied to the word line, to store a “PROGRAM” state, to store a cell state 190-a). This may cause the electric field across features of the memory cell 105 (e.g., between the gate 115 and channel portion 130) such that a first polarization is induced into the ferroelectric portion 125 of the target memory cell 105, a positive charge is injected into a portion of the target memory cell 105, or both.

In such examples (e.g., program operation), the first polarization in the ferroelectric portion 125 may create a first dipole, where a concentration (e.g., a localization) of positive charges may be stored at a first side of the ferroelectric portion 125 and a concentration (e.g., a localization) of negative charges may be stored at a second side of the ferroelectric portion 125 opposite the first side. In such examples, the first side of the ferroelectric portion 125 may be in contact with or otherwise toward the channel portion 130 of the target memory cell 105, while the second side of the ferroelectric portion 125 may be in contact with the channel interlayer portion of the target memory cell 105 or otherwise toward a gate 115.

In one example, to write a logic state to the memory cell 105-a-1, a memory device 100 (e.g., a word line component 155) may bias the word line 150-a-1 (e.g., a selected word line 150) with a first voltage (e.g., relatively high voltage, V), while also biasing non-selected word lines 150, such as non-selected even word lines 150 and non-selected odd word lines 150, with a second voltage, where the second voltage (e.g., V/2) may be between a ground voltage and the first voltage. The memory device 100 (e.g., a pillar component 165) may bias the bit line 160-a-11 and the source line 160-b-11 (e.g., selected bit and source lines) with the ground voltage, while also biasing non-selected bit lines 160-a and non-selected source lines 160-b with the second voltage (e.g., V/2). Table 1 illustrates the various voltages applied to the gates 115, first nodes 135-a (e.g., drains), and the second nodes 135-b during such a write operation:

TABLE 1
Node Voltages during Write Operations

| | | First | Second | |
|---|---|---|---|---|
| | Gate | node | node | |
| Memory cell | Voltage | Voltage | Voltage | V_Ox |
| Memory cell 105-a-1 | V | Ground | Ground | V |
| Memory cell 105-a-2 | V/2 | Ground | Ground | V/2 |
| Memory cell 105-b-1 | V | V/2 | V/2 | V/2 |
| Memory cell 105-b-2 | V/2 | V/2 | V/2 | 0 |
| Memory cell 105-c-1 | V | V/2 | V/2 | V/2 |
| Memory cell 105-c-2 | V/2 | V/2 | V/2 | 0 |
| Memory cell 105-d-1 | V | V/2 | V/2 | V/2 |
| Memory cell 105-d-2 | V/2 | V/2 | V/2 | 0 |
| Memory cell 105 positioned at | V/2 | Ground | Ground | V/2 |
| same plane 145 and same pillar | | | | |
| 140 as the memory cell 105-a-1 | | | | |

In such examples, a stored polarization may be induced (e.g., in accordance with a cell state 190-a) by an electric field across the ferroelectric portion 125 based on the biasing of the word line 150-a-1 with the first voltage and the biasing the of the bit line 160-a-11 and the source line 160-b-11 with the ground voltage. Additionally, by biasing the non-selected word lines 150, the non-selected bit lines 160-a, and non-selected source lines 160-b with the second voltage, the non-selected memory cells 105 may have a reduced risk of disturbance (e.g., a relatively low electric field with a relatively low risk of changing polarization of ferroelectric portions 125 of other non-target memory cells 105).

In some examples, to further mitigate the risk of disturbing non-selected memory cells 105, one or more of the applied voltages may be altered. For example, the memory device 100 may bias the word line 150-a-1 (e.g., selected word line 150) with a first voltage (e.g., V), while also biasing non-selected word lines 150, such as non-selected even word lines 150 and non-selected odd word lines 150, with a second voltage, where the second voltage (e.g., V/3) may be between a ground voltage and the first voltage. The memory device 100 may bias the bit line 160-a-11 and the source line 160-b-11 (e.g., selected bit and source lines) with the ground voltage, while also biasing non-selected bit lines 160-a and non-selected source lines 160-b with a third voltage (e.g., 2V/3), which may be greater than the second voltage but less than the first voltage. Table 2 illustrates the various voltages applied to the gates 115, first nodes 135-a (e.g., drains), and the second nodes 135-b during such a write operation:

TABLE 2
Node Voltages during Write Operations

| | | First | Second | |
|---|---|---|---|---|
| | Gate | node | node | |
| Memory cell | Voltage | Voltage | Voltage | V_Ox |
| Memory cell 105-a-1 | V | Ground | Ground | V |
| Memory cell 105-a-2 | V/3 | Ground | Ground | V/3 |
| Memory cell 105-b-1 | V | 2 V/3 | 2 V/3 | V/3 |
| Memory cell 105-b-2 | V/3 | 2 V/3 | 2 V/3 | −V/3 |
| Memory cell 105-c-1 | V | 2 V/3 | 2 V/3 | V/3 |
| Memory cell 105-c-2 | V/3 | 2 V/3 | 2 V/3 | −V/3 |
| Memory cell 105-d-1 | V | 2 V/3 | 2 V/3 | V/3 |
| Memory cell 105-d-2 | V/3 | 2 V/3 | 2 V/3 | −V/3 |
| Memory cell 105 positioned at | V/3 | Ground | Ground | V/3 |
| same plane 145 and same pillar | | | | |
| 140 as the memory cell 105-a-1 | | | | |

In such examples, the polarization may be induced by an electric field across the ferroelectric portion 125 based on the biasing of the word line 150-a-1 with the first voltage and the biasing the of the bit line 160-a-11 and the source line 160-b-11 with the ground voltage. Additionally, by biasing the non-selected word lines 150 with the second voltage and biasing the non-selected bit lines 160-a and non-selected source lines 160-b with the third voltage, the non-selected memory cells 105 may have a reduced risk of disturbance.

In some cases, as part of an erase operation for a memory cell 105 (e.g., to store an “ERASE” state, to store a cell state 190-b), the polarization of charge in the ferroelectric portion 125 of a memory cell may be changed (e.g., reversed). Additionally, in some examples, a charge stored in a portion of the memory cell 105 may be reversed as part of the erase operation. In some cases, respective voltages may be applied to word line(s) 150, bit line(s) 160-a, and source line(s) 160-b, such that a gate 115 of the target memory cell 105 is at a lower voltage than the first node 135-a and the second node 135-b of the target memory cell 105 (e.g., a relatively negative voltage may be applied to the word line). This may cause an electric field across the features of the memory cell 105 (e.g., between the gate 115 and the channel portion 130), such that a second polarization is induced into the ferroelectric portion 125 of the target memory cell 105, a negative charge is injected into a portion of the target memory cell 105, or both.

In such examples (e.g., erase operation), the second polarization of charge in the ferroelectric portion 125 may create a second dipole, where a concentration of negative charges may be stored at the first side of the ferroelectric portion 125 and a concentration of positive charges may be stored at the second side of the ferroelectric portion 125 opposite the first side. In such examples, the first side of the ferroelectric portion 125 may be in contact with or otherwise toward the channel portion 130 of the target memory cell 105, while the second side of the ferroelectric portion 125 may be in contact with the channel interlayer portion of the target memory cell 105 or otherwise toward a gate 115.

In some examples, to erase a logic state of the memory cell 105-a-1, the memory device 100 may bias the word line 150-a-1 (e.g., a selected word line 150) with the ground voltage, while also biasing non-selected word lines 150, such as non-selected even word lines 150 and non-selected odd word lines 150, with a second voltage, where the second voltage (e.g., V/2) may be between the ground voltage and the first voltage (e.g., V) used to program the memory cell 105-a-1. The memory device 100 may bias the bit line 160-a-11 and the source line 160-b-11 (e.g., selected bit and source lines) with the first voltage (e.g., V, the voltage used to program the memory cell 105-a-1), while also biasing non-selected bit lines 160-a and non-selected source lines 160-b with the second voltage (e.g., V/2). Table 3 illustrates the various voltages applied to the gates 115, first nodes 135-a (e.g., drains), and the second nodes 135-b during such an erase operation:

TABLE 3
Node Voltages during Erase Operations

| | | First | Second | |
|---|---|---|---|---|
| | Gate | node | node | |
| Memory cell | Voltage | Voltage | Voltage | V_Ox |
| Memory cell 105-a-1 | Ground | V | V | −V |
| Memory cell 105-a-2 | V/2 | V | V | −V/2 |
| Memory cell 105-b-1 | Ground | V/2 | V/2 | −V/2 |
| Memory cell 105-b-2 | V/2 | V/2 | V/2 | 0 |
| Memory cell 105-c-1 | Ground | V/2 | V/2 | −V/2 |
| Memory cell 105-c-2 | V/2 | V/2 | V/2 | 0 |
| Memory cell 105-d-1 | Ground | V/2 | V/2 | −V/2 |
| Memory cell 105-d-2 | V/2 | V/2 | V/2 | 0 |
| Memory cell 105 positioned at | V/2 | V | V | −V/2 |
| same plane 145 and same pillar | | | | |
| 140 as the memory cell 105-a-1 | | | | |

In such examples, a stored polarization of the ferroelectric portion 125 may be changed (e.g., removed, reversed, altered, in accordance with a cell state 190-b) based on the biasing of the word line 150-a-1 with the ground voltage and the biasing the bit line 160-a-11 and the source line 160-b-11 with the first voltage. Additionally, by biasing the non-selected word lines 150, the non-selected bit lines 160-a, and non-selected source lines 160-b with the second voltage, the non-selected memory cells 105 may have a reduced risk of disturbance.

In some examples, to further mitigate the risk of disturbing non-selected memory cells 105, one or more of the applied voltages may be altered. For example, the memory device 100 may bias the word line 150-a-1 (e.g., a selected word line 150) with the ground voltage, while also biasing non-selected word lines 150, such as non-selected even word lines 150 and non-selected odd word lines 150, with a second voltage, where the second voltage (e.g., 2V/3) may be between the ground voltage and the first voltage (e.g., V) used to program the memory cell 105-a-1. The memory device 100 may bias the bit line 160-a-11 and the source line 160-b-11 (e.g., selected bit and source lines) with the first voltage (e.g., V, the voltage used to program the memory cell 105-a-1), while also biasing non-selected bit lines 160-a and non-selected source lines 160-b with a third voltage (e.g., V/3), where the third voltage is less than the first and second voltages. Table 4 illustrates the various voltages applied to the gates 115, first nodes 135-a (e.g., drains), and the second nodes 135-b during such an erase operation:

TABLE 4
Node Voltages during Erase Operations

| | | First | Second | |
|---|---|---|---|---|
| | Gate | node | node | |
| Memory cell | Voltage | Voltage | Voltage | V_Ox |
| Memory cell 105-a-1 | Ground | V | V | −V |
| Memory cell 105-a-2 | 2 V/3 | V | V | −V/3 |
| Memory cell 105-b-1 | Ground | V/3 | V/3 | −V/3 |
| Memory cell 105-b-2 | 2 V/3 | V/3 | V/3 | V/3 |
| Memory cell 105-c-1 | Ground | V/3 | V/3 | −V/3 |
| Memory cell 105-c-2 | 2 V/3 | V/3 | V/3 | V/3 |
| Memory cell 105-d-1 | Ground | V/3 | V/3 | −V/3 |
| Memory cell 105-d-2 | 2 V/3 | V/3 | V/3 | V/3 |
| Memory cell 105 positioned at | 2 V/3 | V | V | −V/3 |
| same plane 145 and same pillar | | | | |
| 140 as the memory cell 105-a-1 | | | | |

In such examples, a stored polarization of the ferroelectric portion 125 may be changed based on the biasing of the word line 150-a-1 with the ground voltage and the biasing the of the bit line 160-a-11 and the source line 160-b-11 with the first voltage. Additionally, by biasing non-selected word lines 150 with the second voltage and biasing non-selected bit lines 160-a and non-selected source lines 160-b with the third voltage, non-selected memory cells 105 may have a reduced risk of disturbance.

In some cases, as part of a read operation for a target memory cell 105, a positive voltage may be applied to the corresponding bit line 160-a, while the corresponding source line 160-b may be grounded or otherwise biased with a voltage lower than the voltage applied to the bit line 160-a. Additionally, the corresponding word line 150 may be biased with a positive voltage (e.g., to potentially activate the memory cell 105, based on a level of charge stored in the ferroelectric portion 125), which may be greater than the positive voltage applied to the corresponding bit line 160-a but may be less than a voltage applied during programming of the target memory cell 105. In this way, by biasing the corresponding bit line 160-a, the source line 160-b, and the word line 150, the logic value of the target memory cell 105 may be read (e.g., evaluating whether the target memory cell 105 stores a cell state 190-a or a cell state 190-b).

For example, to read from to the memory cell 105-a-1, the memory device 100 may bias the word line 150-a-1 with a second voltage (e.g., V′), where the second voltage may be less than the first voltage (e.g., V) used to program the memory cell 105-a-1, as described herein. Additionally, the word line component 155 may bias the non-selected word lines 150, such as non-selected even word lines 150 and non-selected odd word lines 150, with the ground voltage. The pillar component 165 may bias the bit line 160-a-11 with a third voltage (e.g., V″), which may be less than the second voltage (e.g., V″<V′<V), and bias the source line 160-b-11 with the ground voltage. Additionally, the memory device 100 may bias non-selected bit lines 160-a and non-selected source lines 160-b with the ground voltage. In this way, a current may flow or may not flow across the memory cell 105-a-1 (e.g., between the bit line 160-a-11 and the source line 160-b-11) depending on a polarization stored in the ferroelectric portion 125 of the target memory cell 105-a-1, a charge stored in a charge-trapping portion of the target memory cell 105-a-1, or a combination thereof.

A signal on the bit line 160-a-11 corresponding to the memory cell 105-a-1 (e.g., an amount of current, such as a current below or above a threshold) may be sensed (e.g., by a sense component 170) and may indicate whether the memory cell 105-a-1 became conductive (e.g., if written to a cell state 190-a) or remained non-conductive (e.g., if written with a cell state 190-b) in response to the application of the various voltages. The sensed signal thus may be indicative of whether the memory cell 105 was in an erased state (e.g., an “ERASE” state, storing a logic 1) or a programmed state (e.g., a “PROGRAM” state, storing a logic 0), or some other state (e.g., of a multiple-level configuration of the memory cell 105-a-1). That is, the sense component 170 may determine a logic state of the memory cell 105-a-1 based on the signal generated on the bit line 160-a-11 according to biasing the word line 150-a-1 with the second voltage, biasing the source line 160-b-11 with the ground voltage, and on biasing the bit line 160-a-11 with the third voltage.

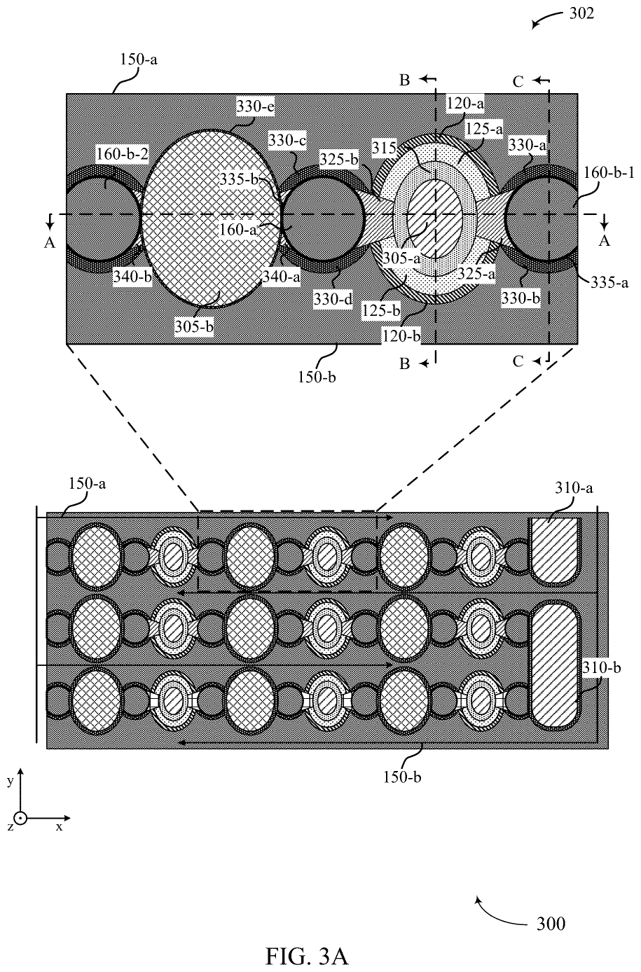

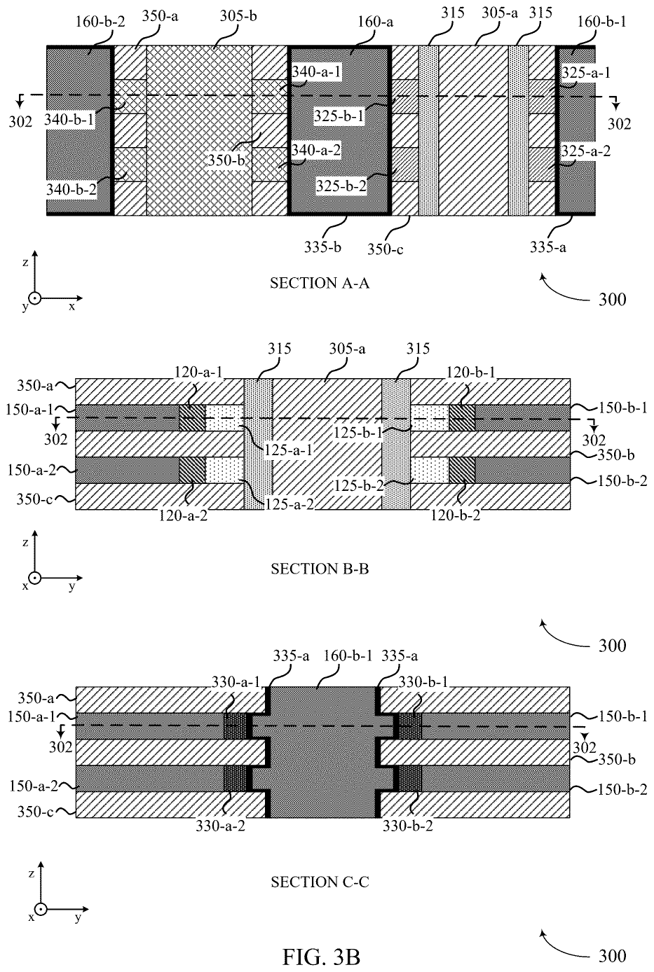

FIGS. 3A and 3B show an architecture 300 (e.g., a material architecture, a memory array) that supports FeNOR memory architectures in accordance with examples as disclosed herein. Aspects of the architecture 300 may implement, or be implemented by, aspects of a memory device 100, an architecture 200, or both. For example, the architecture 300 may include one or more memory cells 105 configured in a pier and pillar architecture, as described herein. The architecture 300 may provide for increased memory density and improved read performances. Aspects of the architecture 300 (e.g., including detail cross-sectional view 302) may be described with reference to an x-direction, a y-direction, and a z-direction of the illustrated coordinate system.

The architecture 300 may include multiple pillars 305-a formed into a stack of materials, which may include an alternation (e.g., along the z-direction) between word line decks (e.g., word lines 150) and oxide layers 350, such that each pillar 305-a may be positioned between a respective source line 160-b (e.g., a conductive pillar) and a respective bit line 160-a (e.g., another conductive pillar pillar). For example, a pillar 305-a may be positioned between the bit line 160-a and the source line 160-b-1. Each pillar 305-a may include a core dielectric material (e.g., silicon dioxide) that extends through the stack of materials along the z-direction, and a first semiconductor material 315 (e.g., p-type doped polysilicon, of one or more channel portions 130) around the core dielectric material that extends along the length of the pillar 305-a along the z-direction.

The architecture 300 may include multiple word line decks, and each word line deck may include a one or more odd word lines 150-a (e.g., a first conductor, which may include ruthenium (Ru), tungsten (W), or molybdenum (Mo)) and one or more even word lines 150-b (e.g., a second conductor, interleaved with odd word lines 150-a, which also may include Ru, W, or Mo). Such even and odd word lines 150 may be separated (e.g., isolated, along the x-direction) via dielectric structures 310-a and 310-b.

As illustrated, a respective combination of pillars 305-a, bit lines 160-a, and source lines 160-b may be separated (e.g., isolated, along the x-direction) via a dielectric pillar 305-b (e.g., aluminum oxide (AIOx), hafnium oxide (HfOx), silicon oxycarbide (SIOC), silicon carbonitride (SiCN), silicon dioxide, or a combination thereof), such that each bit line 160-a and each source line 160-b is coupled with a single pillar 305-a. For example, the dielectric pillar 305-b may separate (e.g., isolate) the bit line 160-a from the source line 160-b-2.

The first semiconductor material 315 of each pillar 305-a may be coupled with (e.g., in contact with) one or more first ferroelectric portions 125-a at a first side of the pillar 305-a, including examples in which multiple first ferroelectric portions 125-a are distributed along the pillar 305-a (e.g., along the z-direction) and are recessed (e.g., confined, positioned) at each word line deck (e.g., associated with a respective word line 150-a). Each first ferroelectric portion 125-a may be coupled with a respective dielectric portion 120-a (e.g., a word line interlayer, a gate dielectric) that is positioned between a respective word line 150-a and a respective first ferroelectric portion 125-a. In such examples, a combination of a dielectric portion 120-a, a first ferroelectric portion 125-a, and a portion of the first semiconductor material 315 (e.g., of a channel portion 130) may be associated with a memory cell 105. As such, multiple first memory cells 105 may be positioned between a respective word line 150-b and the pillar 305-a at the first side of the pillar 305-a.

Similarly, the first semiconductor material 315 of each pillar 305-a may be coupled with (e.g., in contact with) one or more second ferroelectric portions 125-b at a second side of the pillar 305-a, including examples in which multiple second ferroelectric portions 125-b are distributed along the pillar 305-a, and are recessed at each word line deck (e.g., may be associated with a respective word line 150-b). Each second ferroelectric portion 125-b may be coupled with a respective dielectric portion 120-b (e.g., word line interlayer, a gate dielectric) that is positioned between a respective word line 150-b and a respective second ferroelectric portion 125-b. In such examples, a combination of a dielectric portion 120-b, a second ferroelectric portion 125-b, and a portion of the first semiconductor material 315 may be associated with a memory cell 105. As such, multiple second memory cells 105 may also be positioned between a respective word line 150-b and the pillar 305-a at a second side of the pillar 305-a.

In some implementations, each of the bit lines 160-a may include a core conductor material (e.g., tungsten, molybdenum), which may be coupled with an inner surface of a barrier material 335-b (e.g., titanium silicon (TiSi), tungsten nitride (WN), titanium nitride (TiN)). To avoid shorts between the bit lines 160-a and the word lines 150, the architecture 300 may include multiple portions 330-c of a dielectric material (e.g., AIOx, HfOx, SIOC, SiCN, or a combination thereof) at a first end (e.g., along the y-direction) of the bit line 160-a that each separate the first end of the bit line 160-a from a word line 150 (e.g., even or odd word line). Similarly, the architecture 300 may include multiple portions 330-d at a second end of the bit line 160-a that each separate the bit line 160-a from a word line 150 (e.g., even or odd word line). In some examples, the portions 330-c and 330-d may be recessed at each word line deck (e.g., as illustrated in the cross-sectional view C-C of FIG. 3B). In some other examples, the dielectric material may extend continuously through the architecture 300 along the z-direction.

Similarly, each of the source lines 160-b may include a core conductor material (e.g., tungsten or molybdenum), which may be coupled with an inner surface of a barrier material 335-a (e.g., TiSi, WN, TiN). To avoid shorts between the source lines 160-b and the word lines 150, the architecture 300 may include multiple portions 330-a of the dielectric material at a first end (in the y-direction) of the source line 160-b that each separate the first end of the source line 160-b from the word line 150 (e.g., even or odd word line). Similarly, the architecture 300 may include multiple portions 330-b at a second end of source line 160-b that each separate the source line 160-b from the word line 150 (e.g., even or odd word line). In some examples, the portions 330-a and 330-b may be recessed at each word line deck (e.g., as illustrated in the cross-sectional view C-C of FIG. 3B). In some other examples, the dielectric material may extend continuously through the architecture 300 along the z-direction. Additionally, in some examples, the dielectric pillars 305-b may be surrounded, contiguously, by a portion 330-e of the dielectric material.

Each source line 160-b may be coupled with the first semiconductor material 315, the multiple ferroelectric portions 125, and the dielectric portions 120 of the pillars 305-a via respective first portions 325-a of a second semiconductor material (e.g., n-type doped polysilicon). Similarly, each bit line 160-a may be coupled with the first semiconductor material 315, the multiple ferroelectric portions 125, and the dielectric portions 120 of the pillars 305-a via respective second portions 325-b of a second semiconductor material.

In some examples, each first portion 325-a and second portion 325-b may be recessed (e.g., confined) in a respective word line deck. Accordingly, a respective first portion 325-a, a respective second portion 325-b, and a respective first portion of the semiconductor material 315 (e.g., aligned with the respective word line deck, on one side of a pillar 305-a) may form a first channel between the bit line 160-a and the source line 160-b at a first side of the pillar 305-a, which may be utilized to store (e.g., write), read, or erase a polarization of the respective first ferroelectric portion 125-a. Similarly, a respective first portion 325-a, a respective second portion 325-b, and a respective second portion of the semiconductor material 315 (e.g., aligned with the respective word line deck, on another side of the pillar 305-a) may form a second channel between the bit line 160-a and the source line 160-b at a second side of the pillar 305-a, which may be utilized to store (e.g., write), read, or erase a polarization of the respective second ferroelectric portion 125-b.

In some examples, the source lines 160-b and the bit lines 160-a may be in contact with the dielectric pillars 305-b via respective portions 340 of dielectric material. For example, the bit line 160-a may be in contact with the dielectric pillar 305-b via the portions 340-a, while the source line 160-b-2 may be in contact with the dielectric pillar 305-b via the portions 340-b.

FIG. 3B shows cross-sectional views of the architecture 300. For example, as illustrated in cross-sectional view A-A, the bit line 160-a and the source line 160-b-1 (e.g., each extending along the z-direction) may be coupled with first semiconductor material 315 via respective portions 325 of the second semiconductor material, where each respective portion 325 of the semiconductive material may be recessed at a respective word line deck (e.g., distributed along the z-direction, associated with a respective word line 150 or conductor, overlapping along the z-direction with a respective word line 150 or conductor). For example, the source line 160-b-1 may be coupled with the first semiconductor material 315 via the first portion 325-a-1 (e.g., corresponding to the word line deck including the word line 150-a-1 and the word line 150-b-1) and the second portion 325-a-2 (e.g., corresponding to the word line deck including the word line 150-a-2 and the word line 150-b-2). Similarly, the bit line 160-a may be coupled with the first semiconductor material 315 via the second portion 325-b-1 (e.g., corresponding to the word line deck including the word line 150-a-1 and the word line 150-b-1) and the second portion 325-b-2 (e.g., corresponding to the word line deck including the word line 150-a-2 and the word line 150-b-2).

In some examples, the bit line 160-a and the source lines 160-b may be coupled with the dielectric pillar 305-b via respective portions 340 of a dielectric material, which may provide additional support for the bit line 160-a and the source lines 160-b. For example, the bit line 160-a may be coupled with the dielectric pillar 305-b via the portion 340-a-1 and the portion 340-a-2, while the source line 160-b-2 may be coupled with the dielectric pillar 305-b via the portion 340-b-1 and the portion 340-b-2. Similar structures may be applied between the source line 160-b-1 and another dielectric pillar 305.

As illustrated in cross-sectional view B-B, each ferroelectric portion 125 and dielectric portion 120 may be recessed into a respective word line and be between two respective oxide layers 350. For example, the first ferroelectric portion 125-a-1 and the dielectric portion 120-a-1 may be recessed into word line 150-a-1 and between the oxide layer 350-a and the oxide layer 350-b, while the first ferroelectric portion 125-a-2 and the dielectric portion 120-a-2 may be recessed into the word line 150-a-2 and between the oxide layer 350-b and the oxide layer 350-c. Similarly, the second ferroelectric portion 125-b-1 and the dielectric portion 120-b-1 may be recessed into word line 150-b-1 and between the oxide layer 350-a and the oxide layer 350-b, while the second ferroelectric portion 125-b-2 and the dielectric portion 120-b-2 may be recessed into the word line 150-b-2 and between the oxide layer 350-b and the oxide layer 350-c. Although illustrated as extending through the stack of materials, in some examples, the first semiconductor material 315 may be recessed at each word line deck, such that each ferroelectric portion 125 may be coupled with a respective portion of the first semiconductor material 315.

Accordingly, to access a memory cell 105 that includes the dielectric portion 120-a-1 and the first ferroelectric portion 125-a-1, a voltage may be applied to the word line 150-a-1, which may modulate conductivity of a channel, between the bit line 160-a and the source line 160-b-1, via the dielectric portion 120-a-1, the first ferroelectric portion 125-a-1, and the first semiconductor material 315, as described herein with reference to FIG. 2. Similarly, to access a memory cell 105 that includes the dielectric portion 120-b-1, the first ferroelectric portion 125-b-1, a voltage may be applied to the word line 150-b-1, which may modulate conductivity of a channel, between the bit line 160-a and the source line 160-b-1, via the dielectric portion 120-b-1, the first ferroelectric portion 125-b-1, and the first semiconductor material 315, as described herein with reference to FIG. 2.

As illustrated in the cross-sectional view C-C, the source line 160-b-1 may extend, along the z-direction, through a stack of materials that alternate between the oxide layers 350, including the oxide layer 350-a, the oxide layer 350-b, and the oxide layer 350-c, and the word lines 150, including the word line 150-a-1, including the word line 150-b-1, including the word line 150-a-2, and including the word line 150-b-2. In such examples, the portions 330 may be recessed at each word line deck. For example, the portion 330-a-1 may be recessed into the word line 150-a-1 and be between the oxide layer 350-a and the oxide layer 350-b, while the portion 330-a-2 may be recessed into the word line 150-a-2 and be between the oxide layer 350-b and the oxide layer 350-c. Similarly, the portion 330-b-1 may be recessed into the word line 150-b-1 and be between the oxide layer 350-a and the oxide layer 350-b, while the portion 330-b-2 may be recessed into the word line 150-b-2 and be between the oxide layer 350-b and the oxide layer 350-c. In some other examples, the dielectric material may extend along the source line 160-b-1 (e.g., along the z-direction).

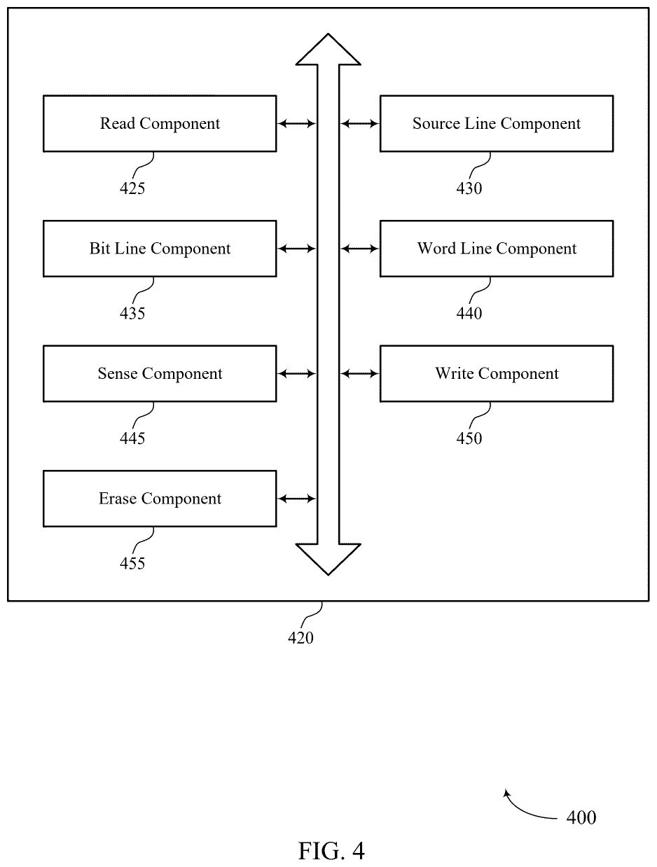

FIG. 4 shows a block diagram 400 of a memory device 420 that supports FeNOR memory architectures in accordance with examples as disclosed herein. The memory device 420 may be an example of aspects of a memory device as described with reference to FIGS. 1 through 3B (e.g., including an architecture 200, including an architecture 300). The memory device 420, or various components thereof, may be an example of means for performing various aspects of FeNOR memory architectures as described herein. For example, the memory device 420 may include a read component 425, a source line component 430, a bit line component 435, a word line component 440, a sense component 445, a write component 450, an erase component 455, or any combination thereof. Each of these components, or components of subcomponents thereof (e.g., one or more processors, one or more memories), may communicate, directly or indirectly, with one another (e.g., via one or more buses).

The memory device 420 may support operations of a memory device in accordance with examples as disclosed herein. For example, the read component 425 may be configured as or otherwise support a means for reading a memory cell of a memory array (e.g., of an FeNOR array). To support the reading (e.g., in coordination with the read component 425), the source line component 430 may be configured as or otherwise support a means for biasing a first pillar of a plurality of first pillars with a first voltage, each of the plurality of first pillars extending along a direction from a substrate and associated with a respective first access line of a plurality of first access lines of the memory array. The bit line component 435 may be configured as or otherwise support a means for biasing a second pillar of a plurality of second pillars with a with a second voltage that is less than the first voltage, each of the plurality of second pillars extending along the direction from the substrate and associated with a respective second access line of a plurality of second access lines of the memory array. The word line component 440 may be configured as or otherwise support a means for biasing an activation line with a third voltage that is greater than the first voltage, the activation line operable to modulate a conductivity of a first channel, between the first pillar and the second pillar and via a portion of a semiconductor material along a first side of a third pillar between the first pillar and the second pillar, based at least in part on an activation line voltage and on a dipole polarization stored in a portion of a ferroelectric material between the activation line and the portion of the semiconductor material. The sense component 445 may be configured as or otherwise support a means for determining a logic state stored in the memory cell based at least in part on a current through the first channel as a result of the biasing of the first pillar with the first voltage, the biasing of the second pillar with the second voltage, and the biasing of the activation line with the third voltage.

In some examples, to support the reading (e.g., in coordination with the read component 425), the source line component 430 may be configured as or otherwise support a means for biasing one or more other first pillars of the plurality of first pillars with the second voltage, and the bit line component 435 may be configured as or otherwise support a means for biasing one or more other second pillars of the plurality of second pillars with the second voltage.

In some examples, to support the reading (e.g., in coordination with the read component 425), the word line component 440 may be configured as or otherwise support a means for biasing one or more second activation lines with the second voltage, where each of the one or more second activation lines is operable to modulate a conductivity of a respective second channel, between the first pillar and the second pillar and via a respective second portion of the semiconductor material along the first side of the third pillar, based at least in part on a respective second activation line voltage and on a dipole polarization stored in a respective second portion of the ferroelectric material between a respective second activation line and the respective second portion of the semiconductor material.

In some examples, to support the reading (e.g., in coordination with the read component 425), the word line component 440 may be configured as or otherwise support a means for biasing one or more third activation lines with the second voltage, where each of the one or more third activation lines is operable to modulate a conductivity of a respective third channel, between the first pillar and the second pillar and via a respective third portion of the semiconductor material along a second side of the third pillar opposite the first side, based at least in part on a respective third activation line voltage and on a dipole polarization stored in a respective third portion of the ferroelectric material between a respective third activation line and the respective third portion of the semiconductor material.

In some examples, the write component 450 may be configured as or otherwise support a means for writing to the memory cell of the memory array. To support the writing (e.g., in coordination with the write component 450), the source line component 430 may be configured as or otherwise support a means for biasing the first pillar and the second pillar with the second voltage. In some examples, the word line component 440 may be configured as or otherwise support a means for biasing the activation line with a fourth voltage that is greater than the third voltage, where the dipole polarization is stored in the portion of the ferroelectric material based at least in part on the biasing of the first pillar and the second pillar with the second voltage and the biasing of the activation line with the fourth voltage.

In some examples, to support the writing (e.g., in coordination with the write component 450), the source line component 430 may be configured as or otherwise support a means for biasing one or more other first pillars of the plurality of first pillars with the fourth voltage, and the bit line component 435 may be configured as or otherwise support a means for biasing one or more other second pillars of the plurality of second pillars with the fourth voltage.

In some examples, to support the writing (e.g., in coordination with the write component 450), the word line component 440 may be configured as or otherwise support a means for biasing one or more second activation lines with a fifth voltage that is between the fourth voltage and the second voltage, where each of the one or more second activation lines is operable to modulate a conductivity of a respective second channel, between the first pillar and the second pillar and via a respective second portion of the semiconductor material along the first side of the third pillar, based at least in part on a respective second activation line voltage and on a dipole polarization stored in a respective second portion of the ferroelectric material between a respective second activation line and the respective second portion of the semiconductor material.

In some examples, to support the writing (e.g., in coordination with the write component 450), the word line component 440 may be configured as or otherwise support a means for biasing one or more third activation lines with a fifth voltage that is between the fourth voltage and the second voltage, where each of the one or more third activation lines is operable to modulate a conductivity of a respective third channel, between the first pillar and the second pillar and via a respective third portion of the semiconductor material along a second side of the third pillar opposite the first side, based at least in part on a respective third activation line voltage and on a dipole polarization stored in a respective third portion of the ferroelectric material between a respective third activation line and the respective third portion of the semiconductor material.

In some examples, the erase component 455 may be configured as or otherwise support a means for erasing the memory cell of the memory array. To support the erasing (e.g., in coordination with the erase component 455), the source line component 430 may be configured as or otherwise support a means for biasing the first pillar and the second pillar with a fourth voltage that is greater than the third voltage. In some examples, the word line component 440 may be configured as or otherwise support a means for biasing the activation line with the second voltage, where the dipole polarization of the portion of the ferroelectric material is reduced or reversed based at least in part on the biasing of the first pillar and the second pillar with the fourth voltage and the biasing of the activation line with the second voltage.

In some examples, to support the erasing (e.g., in coordination with the erase component 455), the source line component 430 may be configured as or otherwise support a means for biasing one or more other first pillars of the plurality of first pillars with a fifth voltage that is between the fourth voltage and the second voltage, and the bit line component 435 may be configured as or otherwise support a means for biasing one or more other second pillars of the plurality of second pillars with the fifth voltage.

In some examples, to support the erasing (e.g., in coordination with the erase component 455), the word line component 440 may be configured as or otherwise support a means for biasing one or more second activation lines with a fifth voltage that is less than the fourth voltage, where each of the one or more second activation lines is operable to modulate a conductivity of a respective second channel, between the first pillar and the second pillar and via a respective second portion of the semiconductor material along the first side of the third pillar, based at least in part on a respective second activation line voltage and on a dipole polarization stored in a respective second portion of the ferroelectric material between a respective second activation line and the respective second portion of the semiconductor material.

In some examples, to support the erasing (e.g., in coordination with the erase component 455), the word line component 440 may be configured as or otherwise support a means for biasing one or more third activation lines with a fifth voltage that is less than the fourth voltage, where each of the one or more third activation lines is operable to modulate a conductivity of a respective third channel, between the first pillar and the second pillar and via a respective third portion of the semiconductor material along a second side of the third pillar opposite the first side, based at least in part on a respective third activation line voltage and on a dipole polarization stored in a respective third portion of the ferroelectric material between a respective third activation line and the respective third portion of the semiconductor material.

In some examples, the described functionality of the memory device 420, or various components thereof, may be supported by or may refer to at least a portion of at least one processor, where such at least one processor may include one or more processing elements (e.g., a controller, a microprocessor, a microcontroller, a digital signal processor, a state machine, discrete gate logic, discrete transistor logic, discrete hardware components, or any combination of one or more of such elements). In some examples, the described functionality of the memory device 420, or various components thereof, may be implemented at least in part by instructions (e.g., stored in memory, non-transitory computer-readable medium) executable by such at least one processor.

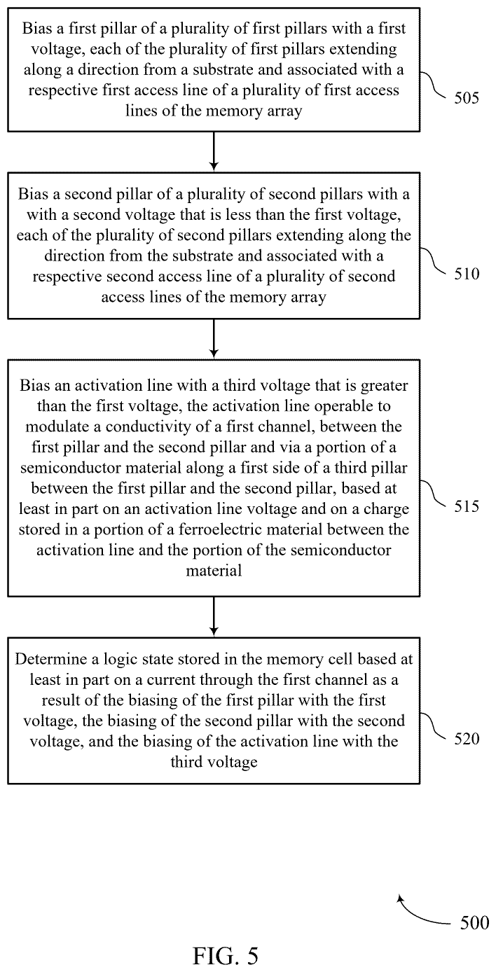

FIG. 5 shows a flowchart illustrating a method 500 that supports FeNOR memory architectures in accordance with examples as disclosed herein. The operations of method 500 may be implemented by a memory device or its components as described herein (e.g., an architecture 200, an architecture 300). For example, the operations of method 500 may be performed by a memory device as described with reference to FIGS. 1 through 4. In some examples, a memory device may execute a set of instructions to control the functional elements of the device to perform the described functions. Additionally, or alternatively, the memory device may perform aspects of the described functions using special-purpose hardware.

At 505, the method may include biasing a first pillar of a plurality of first pillars with a first voltage, each of the plurality of first pillars extending along a direction from a substrate and associated with a respective first access line of a plurality of first access lines of the memory array. In some examples, aspects of the operations of 505 may be performed by a source line component 430 as described with reference to FIG. 4.

At 510, the method may include biasing a second pillar of a plurality of second pillars with a with a second voltage that is less than the first voltage, each of the plurality of second pillars extending along the direction from the substrate and associated with a respective second access line of a plurality of second access lines of the memory array. In some examples, aspects of the operations of 510 may be performed by a bit line component 435 as described with reference to FIG. 4.

At 515, the method may include biasing an activation line with a third voltage that is greater than the first voltage, the activation line operable to modulate a conductivity of a first channel, between the first pillar and the second pillar and via a portion of a semiconductor material along a first side of a third pillar between the first pillar and the second pillar, based at least in part on an activation line voltage and on a dipole polarization stored in a portion of a ferroelectric material between the activation line and the portion of the semiconductor material. In some examples, aspects of the operations of 515 may be performed by a word line component 440 as described with reference to FIG. 4.

At 520, the method may include determining a logic state stored in the memory cell based at least in part on a current through the first channel as a result of the biasing of the first pillar with the first voltage, the biasing of the second pillar with the second voltage, and the biasing of the activation line with the third voltage. In some examples, aspects of the operations of 520 may be performed by a sense component 445 as described with reference to FIG. 4.

In some examples, an apparatus as described herein may perform a method or methods, such as the method 500. The apparatus may include features, circuitry, logic, means, or instructions (e.g., a non-transitory computer-readable medium storing instructions executable by a processor), or any combination thereof for performing the following aspects of the present disclosure:
Aspect 1: A method, apparatus, or non-transitory computer-readable medium including operations, features, circuitry, logic, means, or instructions, or any combination thereof for reading a memory cell of a memory array, where the reading includes; biasing a first pillar of a plurality of first pillars with a first voltage, each of the plurality of first pillars extending along a direction from a substrate and associated with a respective first access line of a plurality of first access lines of the memory array; biasing a second pillar of a plurality of second pillars with a with a second voltage that is less than the first voltage, each of the plurality of second pillars extending along the direction from the substrate and associated with a respective second access line of a plurality of second access lines of the memory array; biasing an activation line with a third voltage that is greater than the first voltage, the activation line operable to modulate a conductivity of a first channel, between the first pillar and the second pillar and via a portion of a semiconductor material along a first side of a third pillar between the first pillar and the second pillar, based at least in part on an activation line voltage and on a dipole polarization stored in a portion of a ferroelectric material between the activation line and the portion of the semiconductor material; and determining a logic state stored in the memory cell based at least in part on a current through the first channel as a result of the biasing of the first pillar with the first voltage, the biasing of the second pillar with the second voltage, and the biasing of the activation line with the third voltage.
Aspect 2: The method, apparatus, or non-transitory computer-readable medium of aspect 1, where the reading further includes operations, features, circuitry, logic, means, or instructions, or any combination thereof for biasing one or more other first pillars of the plurality of first pillars with the second voltage and biasing one or more other second pillars of the plurality of second pillars with the second voltage.
Aspect 3: The method, apparatus, or non-transitory computer-readable medium of any of aspects 1 through 2, where the reading further includes operations, features, circuitry, logic, means, or instructions, or any combination thereof for biasing one or more second activation lines with the second voltage, where each of the one or more second activation lines is operable to modulate a conductivity of a respective second channel, between the first pillar and the second pillar and via a respective second portion of the semiconductor material along the first side of the third pillar, based at least in part on a respective second activation line voltage and on a dipole polarization stored in a respective second portion of the ferroelectric material between a respective second activation line and the respective second portion of the semiconductor material.
Aspect 4: The method, apparatus, or non-transitory computer-readable medium of any of aspects 1 through 3, where the reading further includes operations, features, circuitry, logic, means, or instructions, or any combination thereof for biasing one or more third activation lines with the second voltage, where each of the one or more third activation lines is operable to modulate a conductivity of a respective third channel, between the first pillar and the second pillar and via a respective third portion of the semiconductor material along a second side of the third pillar opposite the first side, based at least in part on a respective third activation line voltage and on a dipole polarization stored in a respective third portion of the ferroelectric material between a respective third activation line and the respective third portion of the semiconductor material.
Aspect 5: The method, apparatus, or non-transitory computer-readable medium of any of aspects 1 through 4, further including operations, features, circuitry, logic, means, or instructions, or any combination thereof for writing to the memory cell of the memory array, where the writing includes; biasing the first pillar and the second pillar with the second voltage; and biasing the activation line with a fourth voltage that is greater than the third voltage, where the dipole polarization is stored in the portion of the ferroelectric material based at least in part on the biasing of the first pillar and the second pillar with the second voltage and the biasing of the activation line with the fourth voltage.
Aspect 6: The method, apparatus, or non-transitory computer-readable medium of aspect 5, where the writing further includes operations, features, circuitry, logic, means, or instructions, or any combination thereof for biasing one or more other first pillars of the plurality of first pillars with the fourth voltage and biasing one or more other second pillars of the plurality of second pillars with the fourth voltage.
Aspect 7: The method, apparatus, or non-transitory computer-readable medium of any of aspects 5 through 6, where the writing further includes operations, features, circuitry, logic, means, or instructions, or any combination thereof for biasing one or more second activation lines with a fifth voltage that is between the fourth voltage and the second voltage, where each of the one or more second activation lines is operable to modulate a conductivity of a respective second channel, between the first pillar and the second pillar and via a respective second portion of the semiconductor material along the first side of the third pillar, based at least in part on a respective second activation line voltage and on a dipole polarization stored in a respective second portion of the ferroelectric material between a respective second activation line and the respective second portion of the semiconductor material.
Aspect 8: The method, apparatus, or non-transitory computer-readable medium of any of aspects 5 through 7, where the writing further includes operations, features, circuitry, logic, means, or instructions, or any combination thereof for biasing one or more third activation lines with a fifth voltage that is between the fourth voltage and the second voltage, where each of the one or more third activation lines is operable to modulate a conductivity of a respective third channel, between the first pillar and the second pillar and via a respective third portion of the semiconductor material along a second side of the third pillar opposite the first side, based at least in part on a respective third activation line voltage and on a dipole polarization stored in a respective third portion of the ferroelectric material between a respective third activation line and the respective third portion of the semiconductor material.
Aspect 9: The method, apparatus, or non-transitory computer-readable medium of any of aspects 1 through 8, further including operations, features, circuitry, logic, means, or instructions, or any combination thereof for erasing the memory cell of the memory array, where the erasing includes; biasing the first pillar and the second pillar with a fourth voltage that is greater than the third voltage; and biasing the activation line with the second voltage, where the dipole polarization of the portion of the ferroelectric material is reduced or reversed based at least in part on the biasing of the first pillar and the second pillar with the fourth voltage and the biasing of the activation line with the second voltage.
Aspect 10: The method, apparatus, or non-transitory computer-readable medium of aspect 9, where the erasing further includes operations, features, circuitry, logic, means, or instructions, or any combination thereof for biasing one or more other first pillars of the plurality of first pillars with a fifth voltage that is between the fourth voltage and the second voltage and biasing one or more other second pillars of the plurality of second pillars with the fifth voltage.
Aspect 11: The method, apparatus, or non-transitory computer-readable medium of any of aspects 9 through 10, where the erasing further includes operations, features, circuitry, logic, means, or instructions, or any combination thereof for biasing one or more second activation lines with a fifth voltage that is less than the fourth voltage, where each of the one or more second activation lines is operable to modulate a conductivity of a respective second channel, between the first pillar and the second pillar and via a respective second portion of the semiconductor material along the first side of the third pillar, based at least in part on a respective second activation line voltage and on a dipole polarization stored in a respective second portion of the ferroelectric material between a respective second activation line and the respective second portion of the semiconductor material.
Aspect 12: The method, apparatus, or non-transitory computer-readable medium of any of aspects 9 through 11, where the erasing further includes operations, features, circuitry, logic, means, or instructions, or any combination thereof for biasing one or more third activation lines with a fifth voltage that is less than the fourth voltage, where each of the one or more third activation lines is operable to modulate a conductivity of a respective third channel, between the first pillar and the second pillar and via a respective third portion of the semiconductor material along a second side of the third pillar opposite the first side, based at least in part on a respective third activation line voltage and on a dipole polarization stored in a respective third portion of the ferroelectric material between a respective third activation line and the respective third portion of the semiconductor material.

It should be noted that the methods described herein are possible implementations, and that the operations and the steps may be rearranged or otherwise modified and that other implementations are possible. Furthermore, portions from two or more of the methods may be combined.

An apparatus is described. The following provides an overview of aspects of the apparatus as described herein:
Aspect 13: A memory device, including: a first pillar extending along a direction from a substrate, the first pillar including one or more conductive materials associated with a first access line of a memory array; a second pillar extending along the direction from the substrate, the second pillar including the one or more conductive materials associated with a second access line of the memory array; a third pillar extending along the direction from the substrate and positioned between the first pillar and the second pillar, the third pillar including a first semiconductor material extending along a length of the third pillar; a plurality of first conductors distributed along the direction from the substrate and positioned along a first side of the third pillar, each of the plurality of first conductors associated with a respective one of a plurality of first activation lines of the memory array; a plurality of second conductors distributed along the direction from the substrate and positioned along a second side of the third pillar opposite the first side, each the plurality of second conductors associated with a respective one of a plurality of second activation lines of the memory array; a plurality of first portions of a ferroelectric material distributed along the direction from the substrate and positioned between the third pillar and a respective one of the plurality of first conductors, each of the plurality of first portions of the ferroelectric material associated with a respective one of a plurality of first memory cells of the memory array; a plurality of second portions of the ferroelectric material distributed along the direction from the substrate and positioned between the third pillar and a respective one of the plurality of second conductors, each of the plurality of second portions of the ferroelectric material associated with a respective one of a plurality of second memory cells of the memory array; a plurality of first portions of a second semiconductor material distributed along the direction from the substrate and positioned between the first pillar and the third pillar; and a plurality of second portions of the second semiconductor material distributed along the direction from the substrate and positioned between the second pillar and the third pillar.
Aspect 14: The memory device of aspect 13, where: each of the plurality of first memory cells is operable to store a respective logic state based at least in part on a dipole polarization stored in a respective first portion of the ferroelectric material; and each of the plurality of second memory cells is operable to store a respective logic state based at least in part on a dipole polarization stored in a respective second portion of the ferroelectric material.
Aspect 15: The memory device of any of aspects 13 through 14, where: each of the plurality of first conductors is configured to modulate a conductivity of a respective first channel, between the first pillar and the second pillar, via a respective one of the plurality of first portions of the second semiconductor material, a respective one of the plurality of second portions of the second semiconductor material, and a respective first portion of the first semiconductor material on the first side of the third pillar; and each of the plurality of second conductors is configured to modulate a conductivity of a respective second channel, between the first pillar and the second pillar, via a respective one of the plurality of first portions of the second semiconductor material, a respective one of the plurality of second portions of the second semiconductor material, and a respective second portion of the first semiconductor material on the second side of the third pillar.
Aspect 16: The memory device of aspect 15, where: each of the plurality of first conductors is configured to modulate the conductivity of the respective first channel based at least in part on a voltage being applied to each of the plurality of first conductors and a dipole polarization stored in the respective first portion of the plurality of first portions of the ferroelectric material; and each of the plurality of second conductors is configured to modulate the conductivity of the respective second channel based at least in part on the voltage being applied to each of the plurality of second conductors and a dipole polarization stored in the respective second portion of the plurality of second portions of the ferroelectric material.
Aspect 17: The memory device of any of aspects 13 through 16, further including: a fourth pillar extending along the direction from the substrate and including a dielectric material, the fourth pillar being between the first pillar and a fifth pillar including the one or more conductive materials associated with a third access line of the memory array; and a sixth pillar extending along the direction from the substrate and including the dielectric material, the sixth pillar being between the second pillar and a seventh pillar including the one or more conductive materials associated with a fourth access line of the memory array.
Aspect 18: The memory device of any of aspects 13 through 17, further including: a plurality of first portions of a dielectric material distributed along the direction from the substrate, each of the plurality of first portions of the dielectric material being positioned between a respective one of the plurality of first conductors and a respective one of the plurality of first portions of the ferroelectric material; and a plurality of second portions of the dielectric material distributed along the direction from the substrate, each of the plurality of second portions of the dielectric material being positioned between a respective one of the plurality of second conductors and a respective one of the plurality of second portions of the ferroelectric material.
Aspect 19: The memory device of any of aspects 13 through 18, where each of the first pillar and the second pillar includes: a core conductor material; and a barrier material around the core conductor material.
Aspect 20: The memory device of aspect 19, further including: a plurality of first portions of a dielectric material, each of the plurality of first portions of the dielectric material being between a respective portion of the barrier material and a respective one of the plurality of first conductors; and a plurality of second portions of the dielectric material, each of the plurality of second portions of the dielectric material being between a respective portion of the barrier material and a respective one of the plurality of second conductors.
Aspect 21: The memory device of any of aspects 13 through 20, where: each of the plurality of first portions of the second semiconductor material is associated with a respective first conductor of the plurality of first conductors and a respective second conductor of the plurality of second conductors; and each of the plurality of second portions of the second semiconductor material is associated with the respective first conductor and the respective second conductor.
Aspect 22: The memory device of any of aspects 13 through 21, where the first semiconductor material is a layer of semiconductor material that is contiguous around a dielectric material of the third pillar.
Aspect 23: The memory device of any of aspects 13 through 22, where the first semiconductor material includes p-type doped polysilicon and the second semiconductor material includes n-type doped polysilicon.

An apparatus is described. The following provides an overview of aspects of the apparatus as described herein:
Aspect 24: A memory device, including: a plurality of portions of a first semiconductor material; a first activation line of a memory array being positioned along a first side of each of the plurality of portions of the first semiconductor material; a second activation line of the memory array being positioned along a second side of each of the plurality of portions of the first semiconductor material opposite the first side; a plurality of first portions of a ferroelectric material, each of the plurality of first portions of the ferroelectric material being positioned between the first activation line and a respective one of the plurality of portions of the first semiconductor material and being associated with a respective first memory cell of a plurality of first memory cells of the memory array; a plurality of second portions of the ferroelectric material, each of the plurality of second portions of the ferroelectric material being positioned between the second activation line and a respective one of the plurality of portions of the first semiconductor material and being associated with a respective second memory cell of a plurality of second memory cells of the memory array; a plurality of first portions of a second semiconductor material, each of the plurality of first portions of the second semiconductor material being positioned between a respective first access line of a plurality of first access lines and a respective one of the plurality of portions of the first semiconductor material; and a plurality of second portions of the second semiconductor material, each of the plurality of second portions of the second semiconductor material being positioned between a respective second access line of a plurality of second access lines and a respective one of the plurality of portions of the first semiconductor material.
Aspect 25: The memory device of aspect 24, where: each of the plurality of first memory cells is operable to store a respective logic state based at least in part on a dipole polarization stored in a respective first portion of the plurality of first portions of the ferroelectric material; and each of the plurality of second memory cells is operable to store a respective logic state based at least in part on a dipole polarization stored in a respective second portion of the plurality of second portions of the ferroelectric material.
Aspect 26: The memory device of any of aspects 24 through 25, further including: a plurality of first portions of a dielectric material, each of the plurality of first portions of the dielectric material positioned between the first activation line and a respective one of the plurality of first portions of the ferroelectric material; and a plurality of second portions of the dielectric material, each of the plurality of second portions of the dielectric material positioned between the second activation line and a respective one of the plurality of second portions of the ferroelectric material.
Aspect 27: The memory device of any of aspects 24 through 26, where the first semiconductor material includes p-type doped polysilicon and the second semiconductor material includes n-type doped polysilicon.
Aspect 28: The memory device of any of aspects 24 through 27, where each of the plurality of portions of the first semiconductor material is around a respective portion of a dielectric material.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to condition of moving from an open-circuit relationship between components in which signals are not presently capable of being communicated between the components over a conductive path to a closed-circuit relationship between components in which signals can be communicated between components over the conductive path. When a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other when the switch is open. When a controller isolates two components from one another, the controller affects a change that prevents signals from flowing between the components using a conductive path that previously permitted signals to flow.

The term “layer” or “level” used herein refers to a stratum or sheet of a geometrical structure (e.g., relative to a substrate). Each layer or level may have three dimensions (e.g., height, width, and depth) and may cover at least a portion of a surface. For example, a layer or level may be a three dimensional structure where two dimensions are greater than a third, e.g., a thin-film. Layers or levels may include different elements, components, or materials. In some examples, one layer or level may be composed of two or more sublayers or sublevels.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In other cases, the substrate may be a silicon-on-insulator (SOI) substrate, such as silicon-on-glass (SOG) or silicon-on-sapphire (SOS), or epitaxial layers of semiconductor materials on another substrate. The conductivity of the substrate, or sub-regions of the substrate, may be controlled through doping using various chemical species including, but not limited to, phosphorus, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected with other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as a n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” when a voltage greater than or equal to the transistor's threshold voltage is applied to the transistor gate. The transistor may be “off” or “deactivated” when a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration,” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a dash and a second label that distinguishes among the similar components. If just the first reference label is used in the specification, the description is applicable to any one of the similar components having the same first reference label irrespective of the second reference label.

The functions described herein may be implemented in hardware, software executed by a processing system (e.g., one or more processors, one or more controllers, control circuitry processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A memory device, comprising:
a first pillar extending along a direction from a substrate, the first pillar comprising one or more conductive materials associated with a first access line of a memory array;
a second pillar extending along the direction from the substrate, the second pillar comprising the one or more conductive materials associated with a second access line of the memory array;
a third pillar extending along the direction from the substrate and positioned between the first pillar and the second pillar, the third pillar comprising a first semiconductor material extending along a length of the third pillar;
a plurality of first conductors distributed along the direction from the substrate and positioned along a first side of the third pillar, each of the plurality of first conductors associated with a respective one of a plurality of first activation lines of the memory array;
a plurality of second conductors distributed along the direction from the substrate and positioned along a second side of the third pillar opposite the first side, each the plurality of second conductors associated with a respective one of a plurality of second activation lines of the memory array;
a plurality of first portions of a ferroelectric material distributed along the direction from the substrate and positioned between the third pillar and a respective one of the plurality of first conductors, each of the plurality of first portions of the ferroelectric material associated with a respective one of a plurality of first memory cells of the memory array;
a plurality of second portions of the ferroelectric material distributed along the direction from the substrate and positioned between the third pillar and a respective one of the plurality of second conductors, each of the plurality of second portions of the ferroelectric material associated with a respective one of a plurality of second memory cells of the memory array;
a plurality of first portions of a second semiconductor material distributed along the direction from the substrate and positioned between the first pillar and the third pillar; and
a plurality of second portions of the second semiconductor material distributed along the direction from the substrate and positioned between the second pillar and the third pillar.

2. The memory device of claim 1, wherein:
each of the plurality of first memory cells is operable to store a respective logic state based at least in part on a dipole polarization stored in a respective first portion of the ferroelectric material; and
each of the plurality of second memory cells is operable to store a respective logic state based at least in part on a dipole polarization stored in a respective second portion of the ferroelectric material.

3. The memory device of claim 1, wherein:
each of the plurality of first conductors is configured to modulate a conductivity of a respective first channel, between the first pillar and the second pillar, via a respective one of the plurality of first portions of the second semiconductor material, a respective one of the plurality of second portions of the second semiconductor material, and a respective first portion of the first semiconductor material on the first side of the third pillar; and
each of the plurality of second conductors is configured to modulate a conductivity of a respective second channel, between the first pillar and the second pillar, via a respective one of the plurality of first portions of the second semiconductor material, a respective one of the plurality of second portions of the second semiconductor material, and a respective second portion of the first semiconductor material on the second side of the third pillar.

4. The memory device of claim 3, wherein:
each of the plurality of first conductors is configured to modulate the conductivity of the respective first channel based at least in part on a voltage being applied to each of the plurality of first conductors and a dipole polarization stored in the respective first portion of the plurality of first portions of the ferroelectric material; and
each of the plurality of second conductors is configured to modulate the conductivity of the respective second channel based at least in part on the voltage being applied to each of the plurality of second conductors and a dipole polarization stored in the respective second portion of the plurality of second portions of the ferroelectric material.

5. The memory device of claim 1, further comprising:
a fourth pillar extending along the direction from the substrate and comprising a dielectric material, the fourth pillar being between the first pillar and a fifth pillar comprising the one or more conductive materials associated with a third access line of the memory array; and
a sixth pillar extending along the direction from the substrate and comprising the dielectric material, the sixth pillar being between the second pillar and a seventh pillar comprising the one or more conductive materials associated with a fourth access line of the memory array.

6. The memory device of claim 1, further comprising:
a plurality of first portions of a dielectric material distributed along the direction from the substrate, each of the plurality of first portions of the dielectric material being positioned between a respective one of the plurality of first conductors and a respective one of the plurality of first portions of the ferroelectric material; and
a plurality of second portions of the dielectric material distributed along the direction from the substrate, each of the plurality of second portions of the dielectric material being positioned between a respective one of the plurality of second conductors and a respective one of the plurality of second portions of the ferroelectric material.

7. The memory device of claim 1, wherein each of the first pillar and the second pillar comprises:
a core conductor material; and
a barrier material around the core conductor material.

8. The memory device of claim 7, further comprising:
a plurality of first portions of a dielectric material, each of the plurality of first portions of the dielectric material being between a respective portion of the barrier material and a respective one of the plurality of first conductors; and
a plurality of second portions of the dielectric material, each of the plurality of second portions of the dielectric material being between a respective portion of the barrier material and a respective one of the plurality of second conductors.

9. The memory device of claim 1, wherein:
each of the plurality of first portions of the second semiconductor material is associated with a respective first conductor of the plurality of first conductors and a respective second conductor of the plurality of second conductors; and
each of the plurality of second portions of the second semiconductor material is associated with the respective first conductor and the respective second conductor.

10. The memory device of claim 1, wherein the first semiconductor material is a layer of semiconductor material that is contiguous around a dielectric material of the third pillar.

11. The memory device of claim 1, wherein the first semiconductor material comprises p-type doped polysilicon and the second semiconductor material comprises n-type doped polysilicon.

12. A method for operating a memory device, comprising:
reading a memory cell of a memory array, wherein the reading comprises:
biasing a first pillar of a plurality of first pillars with a first voltage, each of the plurality of first pillars extending along a direction from a substrate and associated with a respective first access line of a plurality of first access lines of the memory array;
biasing a second pillar of a plurality of second pillars with a with a second voltage that is less than the first voltage, each of the plurality of second pillars extending along the direction from the substrate and associated with a respective second access line of a plurality of second access lines of the memory array;
biasing an activation line with a third voltage that is greater than the first voltage, the activation line operable to modulate a conductivity of a first channel, between the first pillar and the second pillar and via a portion of a semiconductor material along a first side of a third pillar between the first pillar and the second pillar, based at least in part on an activation line voltage and on a dipole polarization stored in a portion of a ferroelectric material between the activation line and the portion of the semiconductor material; and
determining a logic state stored in the memory cell based at least in part on a current through the first channel as a result of the biasing of the first pillar with the first voltage, the biasing of the second pillar with the second voltage, and the biasing of the activation line with the third voltage.

13. The method of claim 12, wherein the reading further comprises:
biasing one or more other first pillars of the plurality of first pillars with the second voltage; and
biasing one or more other second pillars of the plurality of second pillars with the second voltage.

14. The method of claim 12, wherein the reading further comprises:
biasing one or more second activation lines with the second voltage, wherein each of the one or more second activation lines is operable to modulate a conductivity of a respective second channel, between the first pillar and the second pillar and via a respective second portion of the semiconductor material along the first side of the third pillar, based at least in part on a respective second activation line voltage and on a dipole polarization stored in a respective second portion of the ferroelectric material between a respective second activation line and the respective second portion of the semiconductor material.

15. The method of claim 12, wherein the reading further comprises:
biasing one or more third activation lines with the second voltage, wherein each of the one or more third activation lines is operable to modulate a conductivity of a respective third channel, between the first pillar and the second pillar and via a respective third portion of the semiconductor material along a second side of the third pillar opposite the first side, based at least in part on a respective third activation line voltage and on a dipole polarization stored in a respective third portion of the ferroelectric material between a respective third activation line and the respective third portion of the semiconductor material.

16. The method of claim 12, further comprising:
writing to the memory cell of the memory array, wherein the writing comprises:
biasing the first pillar and the second pillar with the second voltage; and
biasing the activation line with a fourth voltage that is greater than the third voltage, wherein the dipole polarization is stored in the portion of the ferroelectric material based at least in part on the biasing of the first pillar and the second pillar with the second voltage and the biasing of the activation line with the fourth voltage.

17. The method of claim 16, wherein the writing further comprises:
biasing one or more other first pillars of the plurality of first pillars with the fourth voltage; and
biasing one or more other second pillars of the plurality of second pillars with the fourth voltage.

18. The method of claim 16, wherein the writing further comprises:
biasing one or more second activation lines with a fifth voltage that is between the fourth voltage and the second voltage, wherein each of the one or more second activation lines is operable to modulate a conductivity of a respective second channel, between the first pillar and the second pillar and via a respective second portion of the semiconductor material along the first side of the third pillar, based at least in part on a respective second activation line voltage and on a dipole polarization stored in a respective second portion of the ferroelectric material between a respective second activation line and the respective second portion of the semiconductor material.

19. The method of claim 16, wherein the writing further comprises:
biasing one or more third activation lines with a fifth voltage that is between the fourth voltage and the second voltage, wherein each of the one or more third activation lines is operable to modulate a conductivity of a respective third channel, between the first pillar and the second pillar and via a respective third portion of the semiconductor material along a second side of the third pillar opposite the first side, based at least in part on a respective third activation line voltage and on a dipole polarization stored in a respective third portion of the ferroelectric material between a respective third activation line and the respective third portion of the semiconductor material.

20. The method of claim 12, further comprising:
erasing the memory cell of the memory array, wherein the erasing comprises:
biasing the first pillar and the second pillar with a fourth voltage that is greater than the third voltage; and
biasing the activation line with the second voltage, wherein the dipole polarization of the portion of the ferroelectric material is reversed based at least in part on the biasing of the first pillar and the second pillar with the fourth voltage and the biasing of the activation line with the second voltage.

21. The method of claim 20, wherein the erasing further comprises:
biasing one or more other first pillars of the plurality of first pillars with a fifth voltage that is between the fourth voltage and the second voltage; and
biasing one or more other second pillars of the plurality of second pillars with the fifth voltage.

22. The method of claim 20, wherein the erasing further comprises:
biasing one or more second activation lines with a fifth voltage that is less than the fourth voltage, wherein each of the one or more second activation lines is operable to modulate a conductivity of a respective second channel, between the first pillar and the second pillar and via a respective second portion of the semiconductor material along the first side of the third pillar, based at least in part on a respective second activation line voltage and on a dipole polarization stored in a respective second portion of the ferroelectric material between a respective second activation line and the respective second portion of the semiconductor material.

23. The method of claim 20, wherein the erasing further comprises:
biasing one or more third activation lines with a fifth voltage that is less than the fourth voltage, wherein each of the one or more third activation lines is operable to modulate a conductivity of a respective third channel, between the first pillar and the second pillar and via a respective third portion of the semiconductor material along a second side of the third pillar opposite the first side, based at least in part on a respective third activation line voltage and on a dipole polarization stored in a respective third portion of the ferroelectric material between a respective third activation line and the respective third portion of the semiconductor material.

24. A memory device, comprising:
a memory array comprising a plurality of memory cells; and
circuitry coupled with the memory array and configured to cause the memory device to read a memory cell of the memory array, wherein the reading comprises:
biasing a first pillar of a plurality of first pillars with a first voltage, each of the plurality of first pillars extending along a direction from a substrate and associated with a respective first access line of a plurality of first access lines of the memory array;
biasing a second pillar of a plurality of second pillars with a with a second voltage that is less than the first voltage, each of the plurality of second pillars extending along the direction from the substrate and associated with a respective second access line of a plurality of second access lines of the memory array;
biasing an activation line with a third voltage that is greater than the first voltage, the activation line operable to modulate a conductivity of a first channel, between the first pillar and the second pillar and via a portion of a semiconductor material along a first side of a third pillar between the first pillar and the second pillar, based at least in part on an activation line voltage and on a dipole polarization stored in a portion of a ferroelectric material between the activation line and the portion of the semiconductor material; and
determining a logic state stored in the memory cell based at least in part on a current through the first channel as a result of the biasing of the first pillar with the first voltage, the biasing of the second pillar with the second voltage, and the biasing of the activation line with the third voltage.
